(19) United States
(12) Patent Application Publication
(10) Pub. No.: US 2015/0155472 A1
(43) Pub. Date: Jun. 4, 2015

(54) POWER GENERATING ELEMENT

(71) Applicant: MITSUMI ELECTRIC CO., LTD., Tokyo (JP)

(72) Inventors: Kenichi Furukawa, Sagamihara-shi (JP); Takayuki Numakunai, Tama-shi (JP)

(73) Assignee: MITSUMI ELECTRIC CO., LTD., Tokyo (JP)

(21) Appl. No.: 14/418,397

(22) PCT Filed: Jul. 25, 2013
(86) PCT No.: PCT/JP2013/070227

§ 371 Date: Jan. 29, 2015

(30) Foreign Application Priority Data
Aug. 1, 2012 (JP) 2012-171395

(51) Int. Cl. H01L 41/12

(52) U.S. Cl. CPC H01L 41/125

(57) ABSTRACT

A power generating element includes a composite rod and a coil. The composite rod is obtained by joining a magnetostrictive rod through which lines of magnetic force pass axially and a reinforcing rod of a non-magnetic material for causing appropriate stress in the magnetostrictive rod and arranged in parallel with the magnetostrictive rod. The coil is provided so that the lines of magnetic force pass axially inside the coil and a voltage is generated based on variation of density of the lines of magnetic force. The power generating element is configured so that the density varies when the other end portion of the composite rod is displaced perpendicular to an axial direction of the composite rod with respect to one end portion of the composite rod to expand or contract the magnetostrictive rod.

### TECHNICAL FIELD

The present invention relates to a power generating element.

### BACKGROUND ART

In recent years, a power generating element which can generate electric power by utilizing variation of magnetic permeability of a magnetostrictive rod formed of a magnetostrictive material has been developed (for example, see patent document 1).

For example, this power generating element described in the patent document 1 includes a pair of magnetostrictive rods arranged in parallel with each other, a coupling yoke for coupling the magnetostrictive rods with each other, coils arranged so as to respectively surround the magnetostrictive rods, a permanent magnet for applying a bias magnetic field to the magnetostrictive rods and a back yoke. When external force is applied to the coupling yoke in a direction perpendicular to an axial direction of the magnetostrictive rods, one of the magnetostrictive rods is deformed so as to be expanded and the other one of the magnetostrictive rods is deformed so as to be contracted. At this time, density of lines of magnetic force (magnetic flux density) passing through each magnetostrictive rod (that is density of lines of magnetic force passing through each coil) varies. As a result of this variation of the density of the lines of magnetic force, a voltage is generated in each coil.

From a point of view of improving power generating efficiency in such a power generating element, it is preferred that only tensile stress is caused in one of the magnetostrictive rods and only compressive stress is caused in the other one of the magnetostrictive rods. However, by analyzing stress actually caused in each magnetostrictive rod used in the power generating element, it has been found that both tensile stress and compressive stress are caused in one magnetostrictive rod as shown in FIG. 10. Namely, it has been found that it is difficult to cause uniform stress (that is only one of the tensile stress and the compressive stress) in one magnetostrictive rod.

Further, from the point of view of improving the power generating efficiency, it is preferred that the winding number of a wire forming each coil is large. However, it is necessary to ensure a relatively large space between the magnetostrictive rods for making the winding number of the wire larger. However, in the case of making the space between the magnetostrictive rods large, there is a case where it becomes more difficult to cause the uniform stress (that is only one of the tensile stress and the compressive stress) in one magnetostrictive rod.

### RELATED ART DOCUMENT

### Patent Document

Patent document 1: WO 2011/158473

### SUMMARY OF THE INVENTION

The present invention has been made in view of the problem mentioned above. Accordingly, it is an object of the present invention to provide a power generating element which can cause uniform stress in a magnetostrictive rod used therein to efficiently generate electric power.

In order to achieve the object described above, the present invention includes the following features (1) to (12).

(1) A power generating element comprising:

a composite rod having one end portion and the other end portion, the composite rod including,
a magnetostrictive rod through which lines of magnetic force pass in an axial direction thereof, the magnetostrictive rod formed of a magnetostrictive material, and
a reinforcing rod having a function of causing appropriate stress in the magnetostrictive rod, the reinforcing rod arranged in parallel with the magnetostrictive rod and formed of a non-magnetic material,
wherein the composite rod is obtained by jointing the magnetostrictive rod and the reinforcing rod through a joint portion; and

a coil provided so that the lines of magnetic force pass inside the coil in an axial direction of the coil and in which a voltage is generated on the basis of variation of density of the lines of magnetic force,

wherein the power generating element is configured so that the density of the lines of magnetic force varies when the other end portion of the composite rod is relatively displaced toward a direction substantially perpendicular to an axial direction of the composite rod with respect to the one end portion of the composite rod to expand or contract the magnetostrictive rod.

(2) The power generating element according to the above (1), wherein when an average value of a cross-sectional area of the magnetostrictive rod is defined as “A” [mm²] and an average value of a cross-sectional area of the reinforcing rod is defined as “B” [mm²], “A” and “B” satisfy a relationship of B/A≧0.8.

(3) The power generating element according to the above (1) or (2), wherein a cross-sectional area of a part of the composite rod corresponding to the joint portion decreases from the one end portion toward the other end portion of the composite rod.

(4) The power generating element according to any one of the above (1) to (3), wherein a cross-sectional area of a part of the reinforcing rod corresponding to the joint portion decreases from the one end portion toward the other end portion of the composite rod, and

wherein a cross-sectional area of the magnetostrictive rod is substantially constant from the one end portion toward the other end portion of the composite rod.

(5) The power generating element according to any one of the above (1) to (4), wherein the coil is arranged around a part of the composite rod corresponding to the joint portion so as to surround the composite rod.

(6) The power generating element according to any one of the above (1) to (5), wherein the coil includes a bobbin arranged around a part of the composite rod corresponding to the joint portion so as to surround the composite rod and a wire wound around the bobbin.

(7) The power generating element according to the above (6), wherein a gap is formed between the composite rod and the bobbin on at least a side of the other end portion of the composite rod.

(8) The power generating element according to the above (7), wherein a displacement of the other end portion of the composite rod is caused by applying vibration to the composite rod, and

wherein the gap is formed so as to have a size so that the bobbin and the composite rod do not mutually interfere with each other while the composite rod is vibrated.

(9) The power generating element according to any one of the above (1) to (8), wherein a Young's modulus of the magnetostrictive material is substantially equal to a Young's modulus of the non-magnetic material.

(10) The power generating element according to any one of the above (1) to (9), wherein a Young's modulus of each of the magnetostrictive material and the non-magnetic material is in the range of 40 to 100 GPa.

(11) The power generating element according to any one of the above (1) to (10), wherein the magnetostrictive material contains an iron-gallium based alloy as a main component thereof.

(12) The power generating element according to any one of the above (1) to (11), wherein the non-magnetic material contains at least one selected from the group consisting of aluminum, magnesium, zinc, copper and an alloy containing at least one of these materials as a main component thereof.

### Effect of the Invention

According to the present invention, it is possible to cause uniform stress in the magnetostrictive rod when the magnetostrictive rod is expanded or contracted by using the composite rod obtained by jointing the magnetostrictive rod and the reinforcing rod which has the function of causing appropriate stress in the magnetostrictive rod. As a result, it is possible to improve the power generating efficiency of the power generating element.

### BRIEF DESCRIPTION OF THE DRAWINGS

FIG. 1 is a perspective view showing a power generating element according to a first embodiment of the present invention.

FIG. 2 is an exploded perspective view showing the power generating element shown in FIG. 1.

FIG. 3 is a planar view showing the power generating element shown in FIG. 1.

FIG. 4 is a longitudinal cross-sectional view (taken along an A-A line shown in FIG. 1) showing the power generating element shown in FIG. 1.

FIG. 5 is an analysis diagram illustrating stress caused in a composite rod.

FIG. 6 is a longitudinal cross-sectional view showing a power generating element according to a second embodiment of the present invention.

FIG. 7 is a longitudinal cross-sectional view showing a power generating element according to a third embodiment of the present invention.

FIG. 8 is a longitudinal cross-sectional view showing a power generating element according to a fourth embodiment of the present invention.

FIG. 9 is a longitudinal cross-sectional view showing a power generating element according to a fifth embodiment of the present invention.

FIG. 10 is an analysis diagram illustrating stress caused in two magnetostrictive rods arranged in parallel with each other.

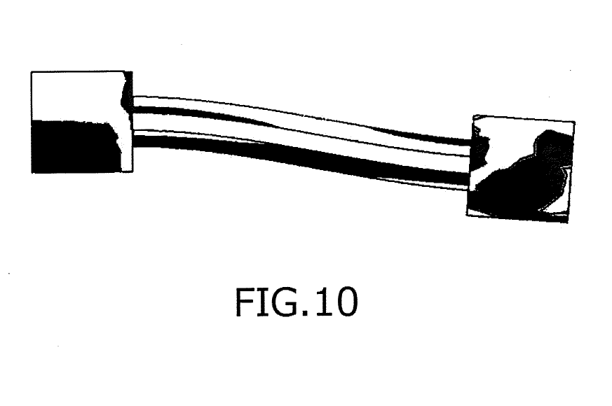

### DETAILED DESCRIPTION OF THE PREFERRED EMBODIMENTS

Hereinafter, a power generating element of the present invention will be described in detail with reference to preferred embodiments shown in the accompanying drawings.

### First Embodiment

First, description will be given to a power generating element according to a first embodiment of the present invention.

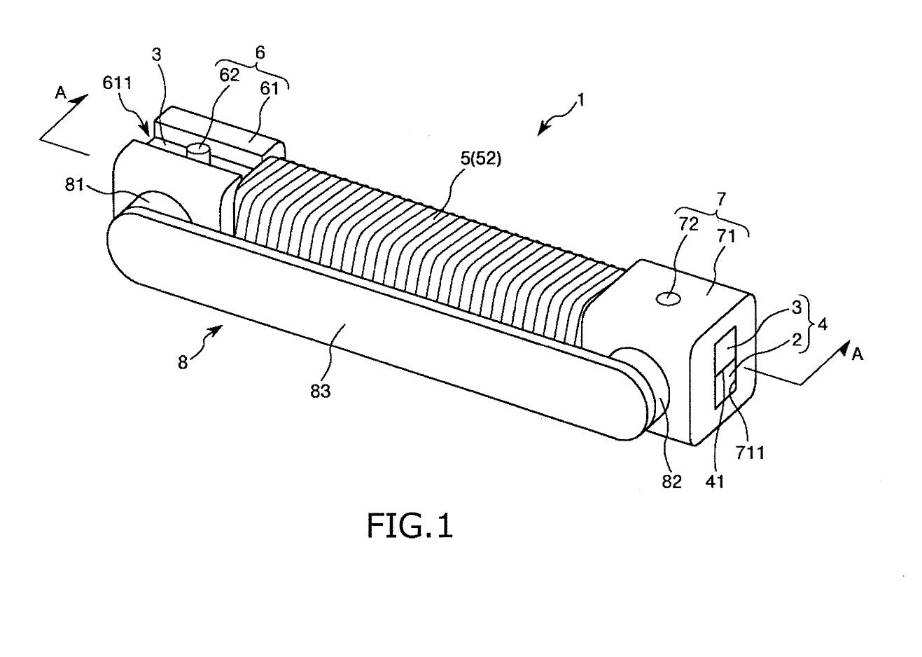

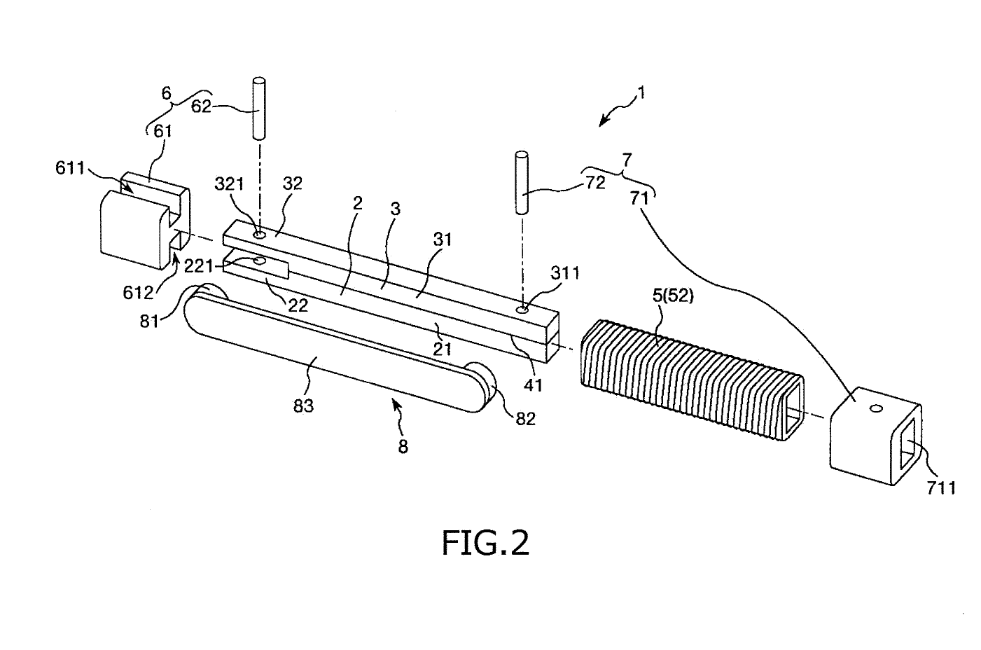

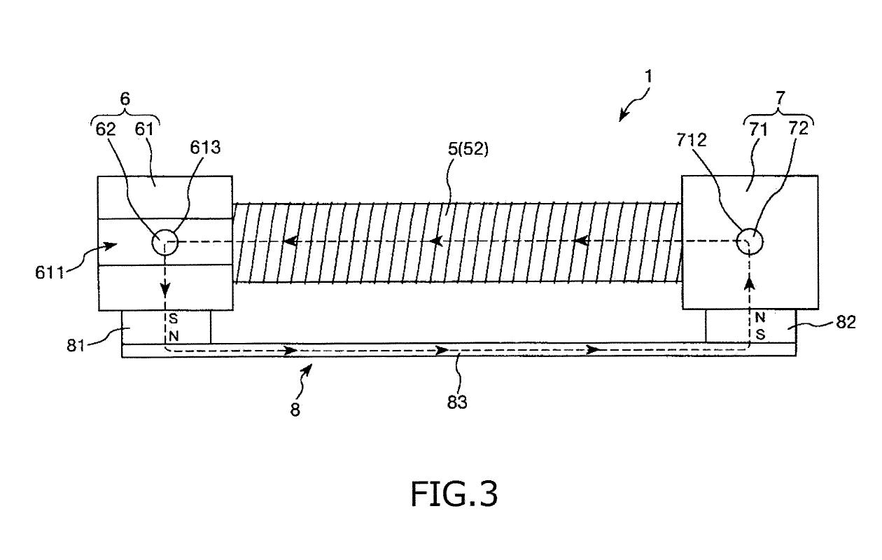

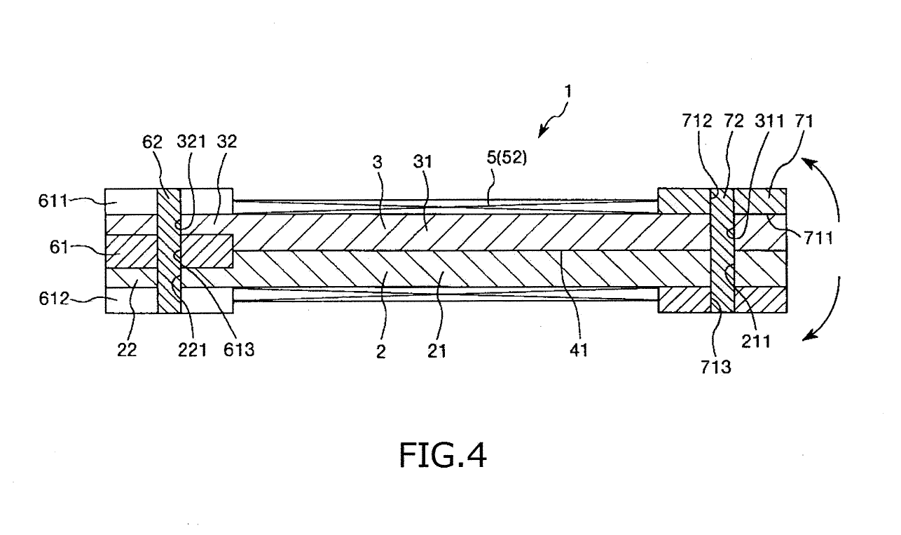

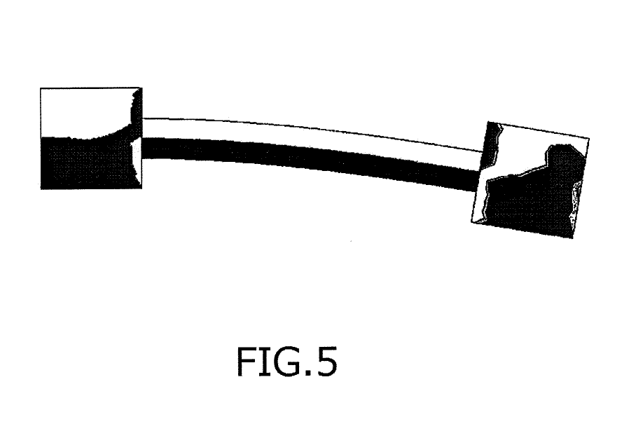

FIG. 1 is a perspective view showing the power generating element according to the first embodiment of the present invention. FIG. 2 is an exploded perspective view showing the power generating element shown in FIG. 1. FIG. 3 is a planar view showing the power generating element shown in FIG. 1. FIG. 4 is a longitudinal cross-sectional view (taken along an A-A line shown in FIG. 1) showing the power generating element shown in FIG. 1. FIG. 5 is an analysis diagram illustrating stress caused in a composite rod.

Hereinafter, an upper side in each of FIGS. 1, 2 and 4 and a front side of the paper in FIG. 3 are referred to as “upper” or “upper side” and a lower side in each of FIGS. 1, 2 and 4 and a rear side of the paper in FIG. 3 are referred to as “lower” or “lower side”. Further, a right side in each of FIGS. 1 to 4 is referred to as “distal side” and a left side in each of FIGS. 1 to 4 is referred to as “proximal side”.

A power generating element 1 shown in FIGS. 1 and 2 has a composite rod 4 obtained by jointing a magnetostrictive rod 2 and a reinforcing rod 3 together, a coil 5 into which the composite rod 4 is inserted, a first coupling portion 6 and a second coupling portion 7 which are respectively provided on both end portions of the composite rod 4 and a magnetic field applying mechanism 8 for applying a bias magnetic field to the magnetostrictive rod 2. The magnetostrictive rod 2 is configured so that lines of magnetic force pass through the magnetostrictive rod 2 in an axial direction of the magnetostrictive rod 2. The reinforcing rod 3 is configured to have a function of causing appropriate stress in the magnetostrictive rod 2 (a function of imparting (applying) appropriate stress to the magnetostrictive rod 2).

In the power generating element 1 having such a configuration, the magnetostrictive rod 2 can be expanded and contracted by displacing a distal end portion (other end portion) of the composite rod 4 in a direction substantially perpendicular to an axial direction of the composite rod 4 with respect to a proximal end portion (one end portion) of the composite rod 4. Namely, the magnetostrictive rod 2 can be expanded and contracted by moving the distal end portion of the composite rod 4 in a vertical direction with respect to the proximal end portion of the composite rod 4 as shown in FIG. 4. At this time, magnetic permeability of the magnetostrictive rod 2 varies due to an inverse magnetostrictive effect. This variation of the magnetic permeability of the magnetostrictive rod 2 leads to variation of density of the lines of magnetic force passing through the magnetostrictive rod 2 (density of lines of magnetic force passing through the coil 5), and thereby generating a voltage in the coil 5.

Hereinafter, description will be given to a configuration of each component of the power generating element 1 of the present invention.

<<Magnetostrictive Rod 2>>

The magnetostrictive rod 2 is formed of a magnetostrictive material and arranged so that a direction in which magnetization is easily generated (an easy magnetization direction) becomes the axial direction thereof. The magnetostrictive rod 2 has a longitudinal square pillar shape so that the lines of magnetic force pass through the magnetostrictive rod 2 in the axial direction thereof.

The magnetostrictive rod 2 includes a main body 21 provided on a distal side of the magnetostrictive rod 2 and a thin wall portion 22 provided on a proximal side of the magnetostrictive rod 2. A thickness of the thin wall portion 22 is thinner than a thickness of the main body 22. The magnetostrictive rod 2 (composite rod 4) is coupled with the first coupling portion 6 through the thin wall portion 22. On the other hand, the magnetostrictive rod 2 (composite rod 4) is coupled with the second coupling portion 7 through a distal end portion of the magnetostrictive rod 2.

In the magnetostrictive rod 2 of this embodiment, the thickness (cross-sectional area) of the main body 21 is substantially constant along the axial direction of the magnetostrictive rod 2. An average thickness of the main body 21 is not particularly limited to a specific value, but is preferably in the range of about 0.3 to 10 mm, and more preferably in the range of about 0.5 to 5 mm. Further, an average value of the cross-sectional area of the main body 21 is preferably in the range of about 0.2 to 200 mm², and more preferably in the range of about 0.5 to 50 mm².

An average thickness of the thin wall portion 22 is not particularly limited to a specific value, but is preferably in the range of about 0.2 to 6 mm, and more preferably in the range of about 0.3 to 3 mm. Further, an average value of the cross-sectional area of the thin wall portion 22 is preferably in the range of about 0.1 to 80 mm², and more preferably in the range of about 0.2 to 20 mm².

With such a configuration, it is possible to reliably pass the lines of magnetic force through the magnetostrictive rod 2 in the axial direction thereof and prevent mechanical strength of the magnetostrictive rod 2 at a boundary portion (level difference portion or step portion) between the main body 21 and the thin wall portion 22 from reducing.

A through-hole 221 is formed in the thin wall portion 22 so as to pass through the thin wall portion 22 in a thickness direction thereof. By inserting a pin 62 of the first coupling portion 6 into the through-hole 221, the magnetostrictive rod 2 (composite rod 4) is fixed to (coupled with) a main body 61 of the first coupling portion 6.

On the other hand, a through-hole 211 is formed in a distal end portion of the main body 21 so as to pass through the distal end portion of the main body 21 in a thickness direction thereof. By inserting a pin 72 of the second coupling portion 7 into the through-hole 211, the magnetostrictive rod 2 (composite rod 4) is fixed to (coupled with) a main body 71 of the second coupling portion 7.

A Young's modulus of the magnetostrictive material is preferably in the range of about 40 to 100 GPa, more preferably in the range of 50 to 90 GPa, and even more preferably in the range of about 60 to 80 GPa. By forming the magnetostrictive rod 2 with the magnetostrictive material having the above Young's modulus, it is possible to expand and contract the magnetostrictive rod 2 more drastically. Since this allows the magnetic permeability of the magnetostrictive rod 2 to vary more drastically, it is possible to more improve the power generating efficiency of the power generating element 1 (the coil 5).

The magnetostrictive material having the above Young's modulus is not particularly limited to a specific kind. Examples of such a magnetostrictive material include an iron-gallium based alloy, an iron-cobalt based alloy, an iron-nickel based alloy and a combination of two or more of these materials. Among them, a magnetostrictive material containing an iron-gallium based alloy (having a Young's modulus of about 70 GPa) as a main component thereof is preferably used. A Young's modulus of the magnetostrictive material containing the iron-gallium based alloy as the main component thereof can be easily adjusted to fall within the above range.

Further, it is preferred that the magnetostrictive material described above contains at least one of rare-earth metal such as Y, Pr, Sm, Tb, Dy, Ho, Er and Tm. By using the magnetostrictive material containing at least one rare-earth metal mentioned above, it is possible to make the variation of the magnetic permeability of the magnetostrictive rod 2 larger.

The reinforcing rod 3 is arranged in parallel with the magnetostrictive rod 2. The composite rod 4 is obtained by jointing the reinforcing rod 3 and the magnetostrictive rod 2 together through a joint portion (joint surface) 41.

<<Reinforcing Rod 3>>

The reinforcing rod 3 is formed of a non-magnetic material. By forming the reinforcing rod 3 with the non-magnetic material, it is possible to allow the lines of magnetic force circulating in the power generating element 1 (the lines of magnetic force passing through the composite rod 4) to selectively pass through the magnetostrictive rod 2 in the axial direction thereof without passing through the reinforcing rod 3 in an axial direction thereof.

The reinforcing rod 3 has the same shape as the shape of the magnetostrictive rod 2. Namely, the reinforcing rod 3 has a longitudinal square pillar shape and includes a main body 31 provided on a distal side of the reinforcing rod 3 and a thin wall portion 32 provided on a proximal side of the reinforcing rod 3. A thickness of the thin wall portion 32 is thinner than a thickness of the main body 31. The reinforcing rod 3 (composite rod 4) is coupled with the first coupling portion 6 through the thin wall portion 32. On the other hand, the reinforcing rod 3 (composite rod 4) is coupled with the second coupling portion 7 through a distal end portion of the reinforcing rod 3.

In the reinforcing rod 3 according to this embodiment, the thickness (cross-sectional area) of the main body 31 is substantially constant along the axial direction thereof. An average thickness (average value of the cross-sectional area) of the main body 31 is not particularly limited to a specific value, but may be set to be equal to the average thickness (average value of the cross-sectional area) of the main body 21 of the magnetostrictive rod 2. In the same manner, an average thickness (average value of the cross-sectional area) of the thin wall portion 32 is not particularly limited to a specific value, but may be set to be equal to the average thickness (average value of the cross-sectional area) of the thin wall portion 22 of the magnetostrictive rod 2.

By setting the average thicknesses of the main body 31 and the thin wall portion 32 of the reinforcing rod 3 as described above, it is possible to allow the reinforcing rod 3 to cause appropriate stress in the magnetostrictive rod 2 with preventing a size of the composite rod 4 (power generating element 1) from getting larger. Further, it is possible to prevent mechanical strength of the reinforcing rod 3 at a boundary portion (level difference portion or step portion) between the main body 31 and the thin wall portion 32 from reducing.

A through-hole 321 is formed in the thin wall portion 32 so as to pass through the thin wall portion 32 in a thickness direction thereof. By inserting the pin 62 of the first coupling portion 6 into the through-hole 321, the reinforcing rod 3 (composite rod 4) is fixed to (coupled with) the main body 62 of the first coupling portion 6.

On the other hand, a through-hole 311 is formed in a distal end portion of the main body 31 so as to pass through the main body 31 in a thickness direction thereof. By inserting the pin 72 of the second coupling portion 7 into the through-hole 311, the reinforcing rod 3 (composite rod 4) is fixed to (coupled with) the main body 71 of the second coupling portion 7.

A Young's modulus of the non-magnetic material forming the reinforcing rod 3 may be different from the Young's modulus of the magnetostrictive material forming the magnetostrictive rod 2, but is preferably substantially equal to the Young's modulus of the magnetostrictive material forming the magnetostrictive rod 2. By forming the reinforcing rod 3 with the non-magnetic material having the Young's modulus substantially equal to the Young's modulus of the magnetostrictive material forming the magnetostrictive rod 2, it is possible to uniform a stiffness of the composite rod 4 in the vertical direction regardless of an entire shape of the composite rod 4, and thereby smoothly and reliably displacing the distal end portion of the composite rod 4 in the direction substantially perpendicular to the axial direction of the composite rod 4 with respect to the proximal end portion of the composite rod 4. In particular, the Young's modulus of the non-magnetic material is preferably in the range of about 40 to 100 GPa, more preferably in the range of about 50 to 90 GPa, and even more preferably in the range of about 60 to 80 GPa.

The non-magnetic material having the above Young's modulus is not particularly limited to a specific kind. Examples of such a non-magnetic material include a metallic material, a semiconductor material, a ceramic material, a resin material and a combination of two or more of these materials. In the case of using the resin material as the non-magnetic material for the reinforcing rod 3, it is preferred that filler is added into the resin material. Among them, a non-magnetic material containing a metallic material as a main component thereof is preferably used. Further, a non-magnetic material containing at least one selected from the group consisting of aluminum, magnesium, zinc, copper and an alloy containing at least one of these materials as a main component thereof is more preferably used.

In this regard, a Young's modulus of each of aluminum and an alloy of aluminum is about 70 GPa, a Young's modulus of each of magnesium and an alloy of magnesium is about 40 GPa. A Young's modulus of each of zinc and an alloy of zinc is about 80 GPa. A Young's modulus of each of copper and an alloy of copper (brass) is about 80 GPa. These metallic materials are low-cost (inexpensive). Further, by using one or more of these metallic materials, it is possible to form the reinforcing rod 3 which can cause appropriate stress in the magnetostrictive rod 2. Thus, it is possible to contribute to reducing a manufacturing cost for the power generating element 1 by using one or more of these metallic materials as the non-magnetic material for the reinforcing rod 3.

The main body 31 of the reinforcing rod 3 having the above configuration and the main body 21 of the magnetostrictive rod 2 are jointed with each other through the joint portion 41 to integrate the reinforcing rod 3 with the magnetostrictive rod 2.

Examples of a method for jointing the reinforcing rod 3 and the magnetostrictive rod 2 (a method for forming the joint portion 41) include an ultrasonic bonding method; a diffusion bonding method such as a solid-phase diffusion bonding method which is carried out by intervening an insert metal in a solid-phase and a liquid-phase diffusion bonding method (TLP bonding method) which is carried out by intervening an insert metal in a liquid-phase; a bonding method using a resin-based adhesive agent such as an epoxy-based adhesive agent; a brazing and soldering method using a metallic brazing material such as gold, silver, copper and a nickel alloy; and a combination of two or more of these methods.

By forming the composite rod 4 by integrating the reinforcing rod 3 with the magnetostrictive rod 2 as described above, it is possible to uniformly cause compressive stress in the magnetostrictive rod 2 when the distal end portion of the composite rod 4 is displaced toward a lower side as shown in FIG. 5. Although this state is not shown in the drawings, it is possible to uniformly cause tensile stress in the magnetostrictive rod 2 when the distal end portion of the composite rod 4 is displaced toward an upper side.

Thus, it is possible to improve a contribution ratio per cubic volume of the magnetostrictive material, which is a high-cost material, with respect to power generation. Namely, it is possible to increase an amount of the magnetostrictive material contributing to the power generation, and thereby achieving weight saving, downsizing and cost reduction of the power generating element 1.

The coil 5 is arranged around a part of the composite rod 4 corresponding to the joint portion 41 thereof so as to surround the composite rod 4 (joint portion 41).

<<Coil 5>>

The coil 5 is formed by winding a wire 52 around the jointing portion 41 so as to surround the part of the composite rod 4 corresponding to the joint portion 41 thereof. With such a configuration, the coil 5 is provided so that the lines of magnetic force passing through the magnetostrictive rod 2 pass inside the coil 5 (an inner cavity of the coil 5) in an axial direction of the coil 5 (in this embodiment, the axial direction of the coil 5 is equivalent to the axial direction of the magnetostrictive rod 2). On the basis of the variation of the magnetic permeability of the magnetostrictive rod 2, that is, on the basis of the variation of the density of the lines of magnetic force (magnetic flux density) passing through the magnetostrictive rod 2, the voltage is generated in the coil 5.

By using the coil 5 having such a configuration, it is possible to eliminate a restriction on a cubic volume of the coil 5. This makes it possible to broaden the range of choice for the winding number of the wire 52 forming the coil 5, a cross-sectional area (wire diameter) of the wire 52 or the like depending on the power generating efficiency, load impedance, a target voltage, a target current or the like.

A constituent material for the wire 52 is not particularly limited to a specific type. Examples of the constituent material for the wire 52 include a wire obtained by covering a copper base line with an insulating layer, a wire obtained by covering a copper base line with an insulating layer to which an adhesive (fusion) function is imparted and a combination of two or more of these wires.

The winding number of the wire 52 is appropriately set depending on the cross-sectional area and the like of the wire 52. The winding number of the wire 52 is not particularly limited to a specific number, but is preferably in the range of about 100 to 500, and more preferably in the range of about 150 to 450.

Further, the cross-sectional area of the wire 52 is preferably in the range of about 5×10⁻⁴ to 0.126 mm², and more preferably in the range of about 2×10⁻³ to 0.03 mm².

A cross-sectional shape of the wire 52 may be any shape. Examples of the cross-sectional shape of the wire 52 include a polygonal shape such as a triangular shape, a square shape, a rectangular shape and a hexagonal shape; a circular shape and an elliptical shape. The first coupling portion 6 is provided on the proximal end portion of the composite rod 4.

<<First Coupling Portion 6>>

The first coupling portion 6 serves as a fixation portion for fixing the power generating element 1 to a casing or the like. When the power generating element 1 is fixed to the casing or the like through the first coupling portion 6, the composite rod 4 is supported in a cantilevered state in which the proximal end portion of the composite rod 4 serves as a fixed end portion and the distal end portion of the composite rod 4 serves as a movable end portion. The first coupling portion 6 includes the main body 61 and the pin 62.

The main body 61 includes a block body having grooves 611, 612 respectively formed on substantially central portions of an upper surface and a lower surface thereof from a distal end toward a proximal end thereof. Namely, the main body 61 has an H-shape when the main body 61 is viewed from a proximal end side (or a distal end side). Further, a through-hole 613 is formed in the main body 61 so as to pass through the main body 61 in a thickness direction thereof. Further, the through-hole 613 is formed so that a position of the through-hole 613 corresponds to central portions of the grooves 611, 612.

At the time of assembling the power generating element 1, the thin wall portion 22 of the magnetostrictive rod 2 is inserted into the groove 612, the thin wall portion 32 of the reinforcing rod 3 is inserted into the groove 611 and then the pin 62 is inserted into the through-holes 321, 613 and 221. As a result, the composite rod 4 is fixed to the first coupling portion 6.

In this embodiment, the pin 62 is formed from a cylindrical body and fixed to the magnetostrictive rod 2, the reinforcing rod 3 and the main body 61 with a fixing method such as an engagement method, a caulking method, a welding method and a bonding method using an adhesive agent. The pin 62 may be formed from a screw capable of screwing with the magnetostrictive rod 2, the reinforcing rod 3 and the main body 61. On the other hand, the second coupling portion 7 is provided on the distal end portion of the composite rod 4.

<<Second Coupling Portion 7>>

The second coupling portion 7 serves as a portion for applying external force or vibration to the composite rod 4. When external force in the upper side or the lower side in FIG. 4 or vibration in the vertical direction in FIG. 4 is applied to the second coupling portion 7, the composite rod 4 starts reciprocating motion in the vertical direction under the cantilevered state in which the proximal end portion of the composite rod 4 serves as the fixed end portion and the distal end portion of the composite rod 4 serves as the movable end portion. In other words, the distal end portion of the composite rod 4 is displaced in the vertical direction with respect to the proximal end portion of the composite rod 4 at this time. The second coupling portion 7 includes the main body 71 and the pin 72.

The main body 71 is formed from a block body in which an inserted portion 711 is formed so as to pass through from a proximal end surface to a distal end surface thereof. Namely, the main body 71 has a rectangular parallelepiped shape. Further, through-holes 712, 713 are respectively formed in central portions of an upper surface and a lower surface of the main body 71 so as to respectively pass through the upper surface and the lower surface in a thickness direction thereof.

At the time of assembling the power generating element 1, the distal end portion of the composite rod 4 is inserted into the inserted portion 711 and then the pin 72 is inserted into the through-holes 712, 311, 211 and 713. As a result, the second coupling portion 7 is fixed to the composite rod 4.

In this embodiment, the pin 72 is formed from a cylindrical body and fixed to the magnetostrictive rod 2, the reinforcing rod 3 and the main body 71 with a fixing method such as an engagement method, a caulking method, a welding method and a bonding method using an adhesive agent. The pin 72 may be formed from a screw capable of screwing with the magnetostrictive rod 2, the reinforcing rod 3 and the main body 71.

A constituent material for each of the main bodies 61, 71 is not particularly limited to a specific kind as long as it has an enough stiffness for reliably fixing the composite rod 4 to each coupling portion 6, 7 and applying uniform stress to the composite rod 4 (in particular, to the magnetostrictive rod 2) and enough ferromagnetism for applying the bias magnetic field to the magnetostrictive rod 2. Examples of the constituent material having the above properties include a pure iron (e.g., “JIS SUY”), a soft iron, a carbon steel, a magnetic steel (silicon steel), a high-speed tool steel, a structural steel (e.g., “JIS SS400”), a stainless permalloy and a combination of two or more of these materials.

A constituent material for each of the pins 62, 72 may be the same material as the constituent material for each of the main bodies 61, 71. Alternatively, the constituent material for each of the pins 62, 72 may be a resin material, a ceramic material or the like.

The magnetic field applying mechanism 8 for applying the bias magnetic field to the magnetostrictive rod 2 is provided on a right lateral side of the composite rod 4.

<<Magnetic Field Applying Mechanism 8>>

As shown in FIGS. 1 and 2, the magnetic field applying mechanism 8 includes a permanent magnet 81 attached to a right lateral surface of the main body 61, a permanent magnet 82 attached to a right lateral surface of the main body 71 and a plate-like yoke 83 for connecting the permanent magnets 81 and 82.

As shown in FIG. 3, the permanent magnet 81 is arranged so that its south pole faces to a side of the main body 61 and its north pole faces to a side of the yoke 83. The permanent magnet 82 is arranged so that its north pole faces to a side of the main body 71 and its south pole faces to the side of the yoke 83. Due to this arrangement, it is possible to form a magnetic field loop circulating in a counterclockwise direction in the power generating element 1.

For example, a constituent material for the yoke 83 may be the same material as the constituent material for each of the main bodies 61, 71. Further, as each of the permanent magnets 81, 82, it is possible to use an alnico magnet, a ferrite magnet, a neodymium magnet, a samarium-cobalt magnet, a magnet (bonded magnet) obtained by molding a composite material prepared by pulverizing and mixing at least one of these magnets with a resin material or a rubber material, or the like. The yoke 83 is preferably fixed to the permanent magnets 81, 82 with, for example, a bonding method using an adhesive agent or the like.

In the power generating element 1 having such a configuration, when the second coupling portion 7 is displaced (rotated) toward the lower side in a state that the first coupling portion 6 is fixed to the casing or the like (referring to FIG. 3), that is, when the distal end portion of the composite rod 4 is displaced toward the lower side with respect to the proximal end portion of the composite rod 4, the magnetostrictive rod 2 is deformed so as to be contracted in the axial direction thereof. On the other hand, when the second coupling portion 7 is displaced (rotated) toward the upper side, that is, when the distal end portion of the composite rod 4 is displaced toward the upper side with respect to the proximal end portion of the composite rod 4, the magnetostrictive rod 2 is deformed so as to be expanded in the axial direction thereof. As a result, the magnetic permeability of the magnetostrictive rod 2 varies due to the inverse magnetostrictive effect. This variation of the magnetic permeability of the magnetostrictive rod 2 leads to the variation of the density of the lines of magnetic force passing through the magnetostrictive rod 2 (density of the lines of magnetic force passing through the inner cavity of the coil 5 along the axial direction of the magnetostrictive rod 2), and thereby generating the voltage in the coil 5.

In particular, the present invention can cause uniform stress (only compressive stress or only tensile stress) in the magnetostrictive rod 2. Thus, it is possible to improve the power generating efficiency of the power generating element 1. Further, it is possible to improve the contribution ratio per cubic volume of the magnetostrictive material with respect to the power generation, and thereby contributing to weight saving, downsizing and cost reduction of the power generating element 1.

An amount of the electric power generated by the power generating element 1 is not particularly limited to a specific value, but is preferably in the range of about 100 to 1400 μJ. If the amount of the electric power generated by the power generating element 1 (power generating capability of the power generating element 1) is in the above range, it is possible to efficiently use the power generating element 1 for a wireless switch for house lighting, a home security system or the like (which are described below) in combination with a wireless communication device.

### Second Embodiment

Next, description will be given to a power generating element according to a second embodiment of the present invention.

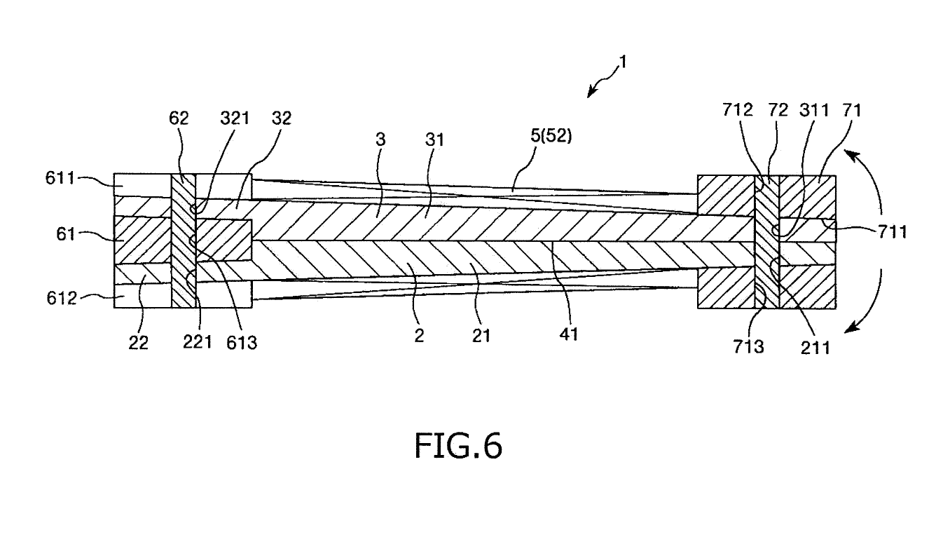

FIG. 6 is a longitudinal cross-sectional view showing the power generating element according to the second embodiment of the present invention. Hereinafter, an upper side in FIG. 6 is referred to as “upper” or “upper side” and a lower side in FIG. 6 is referred to as “lower” or “lower side”. Further, a right side in FIG. 6 is referred to as “distal side” and a left side in FIG. 6 is referred to as “proximal side”.

Hereinafter, the power generating element according to the second embodiment will be described by placing emphasis on the points differing from the power generating element according to the first embodiment, with the same matters being omitted from description.

A power generating element 1 according to the second embodiment has the same configuration as the power generating element 1 according to the first embodiment except that the entire shape of the composite rod 4 is modified. Namely, as shown in FIG. 6, the composite rod 4 according to the second embodiment has a shape in which the thickness in the longitudinal cross-sectional view (cross-sectional area of the composite rod 4) continuously decreases from the proximal end portion toward the distal end portion of the composite rod 4.

As described above, the composite rod 4 has a taper shape in which the thickness on a side of the proximal end portion (the fixed end portion) is thick and the thickness on a side of the distal end portion (the movable end portion) is thin. By using the composite rod 4 having such a taper shape, it is possible to more reliably control distribution of the stress caused in the magnetostrictive rod 2 to more uniformly apply the stress to the magnetostrictive rod 2 in the axial direction thereof. This makes it possible to make a variation amount of the magnetic permeability of the magnetostrictive rod 2 larger, and thereby more improving the power generating efficiency of the power generating element 1. Further, since the stress applied to the magnetostrictive rod 2 becomes more uniform, durability of the magnetostrictive rod 2 against the external force and the vibration is also improved.

The power generating element 1 according to the second embodiment can also provide the same functions/effects as the power generating element 1 according to the first embodiment.

The composite rod 4 may have other taper shapes such as a taper shape in which the cross-sectional area thereof discontinuously decreases from the proximal end portion toward the distal end portion of the composite rod 4.

### Third Embodiment

Next, description will be given to a power generating element according to a third embodiment.

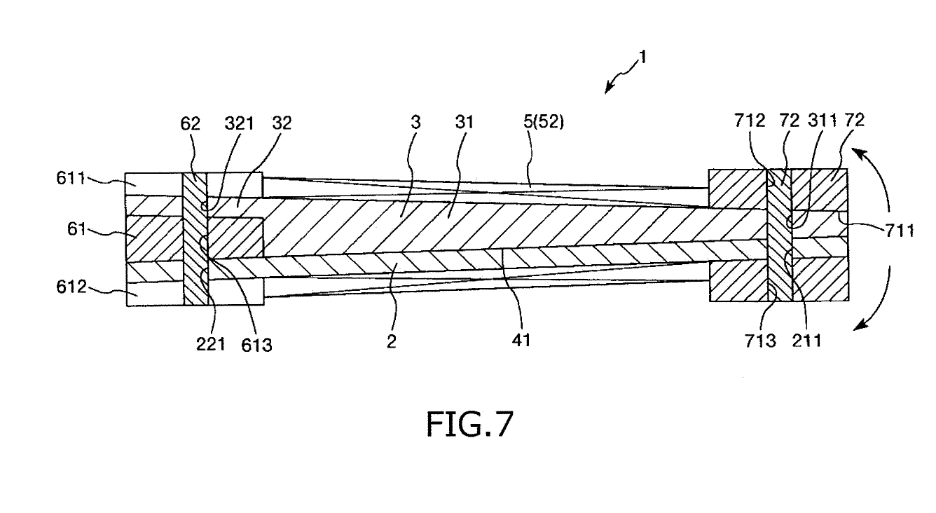

FIG. 7 is a longitudinal cross-sectional view showing the power generating element according to the third embodiment of the present invention. Hereinafter, an upper side in FIG. 7 is referred to as “upper” or “upper side” and a lower side in FIG. 7 is referred to as “lower” or “lower side”. Further, a right side in FIG. 7 is referred to as “distal side” and a left side in FIG. 7 is referred to as “proximal side”.

Hereinafter, the power generating element according to the third embodiment will be described by placing emphasis on the points differing from the power generating elements according to the first embodiment and the second embodiment, with the same matters being omitted from description.

A power generating element 1 according to the third embodiment has the same configuration as the power generating element 1 according to the second embodiment except that the relationship between the thickness of the main body 21 of the magnetostrictive rod 2 and the thickness of the main body 31 of the reinforcing rod 3 is modified. Namely, as shown in FIG. 7, the composite rod 4 according to the third embodiment has a taper shape in which the thickness (cross-sectional area) of the part of the reinforcing rod 3 corresponding to the joint portion 41 (that is the thickness of the main body 31 of the reinforcing rod 3) continuously decreases from the proximal end portion toward the distal end portion of the reinforcing rod 3 and the thickness (cross-sectional area) of the magnetostrictive rod 2 is substantially constant from the proximal end portion toward the distal end portion of the magnetostrictive rod 2.

In the whole of the composite rod 4, areas in which the stress becomes most uniform and largest are concentrated in the vicinity of a surface perpendicular to a displacement direction (rotational direction) of the composite rod 4. Thus, by providing the magnetostrictive rod 2 having a substantially constant thickness perpendicular to the axial direction thereof at this area of the composite rod 4, it is possible to reduce a used amount of the magnetostrictive material for the power generating element 1. Since the magnetostrictive material is a high-cost material, it is possible to more reduce the manufacturing cost for the power generating element 1 with such a configuration.

For such a configuration, the reinforcing rod 3 having the above-mentioned shape which is relatively complex may be formed using a method such as a pressing work, a forging and a casting. On the other hand, the magnetostrictive rod 2 having the above-mentioned shape which is relatively simple may be formed using a method such as a cutting work and a laser machining.

Since the magnetostrictive material (e.g., the iron-gallium based alloy) has a certain level of ductility, it is easy to form the magnetostrictive rod 2 with the method such as the cutting work and the laser machining. However, it is relatively difficult to carry out a bending work, the forgoing or the pressing work to the magnetostrictive material. Further, remaining stress due to the bending work, the forgoing or the pressing work makes an effect on the inverse magnetostrictive effect. Thus, depending on processing conditions, there is possibility that the magnetic permeability of the magnetostrictive rod 2 for passing the lines of magnetic force through the magnetostrictive rod 2 deteriorates. Thus, it is preferred that the shape of the magnetostrictive rod 2 is as simple as possible. In particular, a plate-like shape having a substantially constant thickness is especially suitable for the magnetostrictive rod 2. In this embodiment, since the magnetostrictive rod 2 has such a plate-like shape, it is possible to improve ease of assembly of the power generating element 1 and formability of the magnetostrictive rod 2.

As describe above, according to this embodiment, it is possible to obtain the power generating element 1 which can maximally provide its effects with minimizing the used amount of the magnetostrictive material.

When the average value of the cross-sectional area of the magnetostrictive rod 2 is defined as “A” [mm²] and the average value of the cross-sectional area of the reinforcing rod 3 is defined as “B” [mm²], “A” and “B” preferably satisfy a relationship of B/A≧0.8, more preferably satisfy a relationship of B/A≧1, and even more preferably satisfy a relationship of B/A≧1.2. By setting “A” and “B” to satisfy the above relationship, it is possible to more reliably reduce the manufacturing cost for the power generating element 1 and more improve the power generating efficiency of the power generating element 1.

The power generating element 1 according to the third embodiment can also provide the same functions/effects as the power generating elements 1 according to the first embodiment and the second embodiment.

### Fourth Embodiment

Next, description will be given to a power generating element according to a fourth embodiment.

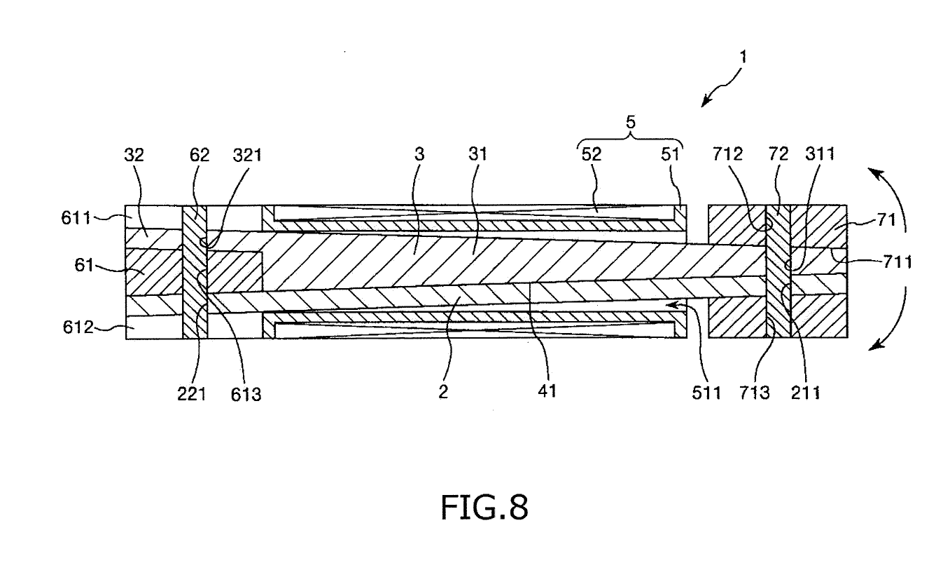

FIG. 8 is a longitudinal cross-sectional view showing the power generating element according to the fourth embodiment of the present invention. Hereinafter, an upper side in FIG. 8 is referred to as “upper” or “upper side” and a lower side in FIG. 8 is referred to as “lower” or “lower side”. Further, a right side in FIG. 8 is referred to as “distal side” and a left side in FIG. 8 is referred to as “proximal side”.

Hereinafter, the power generating element according to the fourth embodiment will be described by placing emphasis on the points differing from the power generating elements according to the first to the third embodiments, with the same matters being omitted from description.

A power generating element 1 according to the fourth embodiment has the same configuration as the power generating element 1 according to the third embodiment except that the arrangement (position) and the configuration of the coil 5 are modified. Namely, as shown in FIG. 8, in the power generating element 1 according to the fourth embodiment, the coil 5 includes a bobbin 51 arranged around the joint portion 41 of the composite rod 4 so as to surround the part of the composite rod 4 corresponding to the joint portion 41 and the wire 52 wound around the bobbin 51.

The bobbin 52 is formed from a rectangular parallelepiped body and fixed to a distal end surface of the main body 61 of the first coupling portion 6 with a fixing method such as an engagement method, a caulking method, a welding method and a bonding method using an adhesive agent. With such a configuration, the composite rod 4 in this embodiment can be displaced inside the bobbin 51 independently from the coil 5. Thus, the wire 52 forming the coil 5 is not deformed even when the composite rod 4 is displaced. This makes it possible to improve durability of the coil 5.

Further, the rectangular parallelepiped body forming the bobbin 52 has an inner cavity having a substantially constant cross-sectional area. Thus, a gap 511 is formed between the composite rod 4 and the bobbin 51. A clearance between the composite rod 4 and the bobbin 51 (that is a width of the gap 511) gradually increases from the proximal end portion toward the distal end portion of the composite rod 4. Further, the gap 511 is formed so as to have a size so that the bobbin 51 and the composite rod 4 do not mutually interfere with each other when the composite rod 4 is displaced by vibration. Namely, the gap 511 is formed so that the size of the gap 511 becomes larger than amplitude of vibration of the composite rod 4. By setting the size of the gap 511 as described above, the power generating element 1 can efficiently generate the electric power.

For example, a constituent material for the bobbin 51 may be the same material as the constituent material for the reinforcing rod 3.

The power generating element 1 according to the fourth embodiment can also provide the same functions/effects as the power generating elements 1 according to the first to the third embodiments.

Further, in a case where the wire 52 of the coil 5 is bundled and integrated to form the gap 511 between the composite rod 4 and the wire 52 of the coil 5, the bobbin 51 may be omitted from the power generating element 1. Further, the gap 511 may be formed between the composite rod 4 and the bobbin 51 along the entire (entire length) of the joint portion 41.

### Fifth Embodiment

Next, description will be given to a power generating element according to a fifth embodiment.

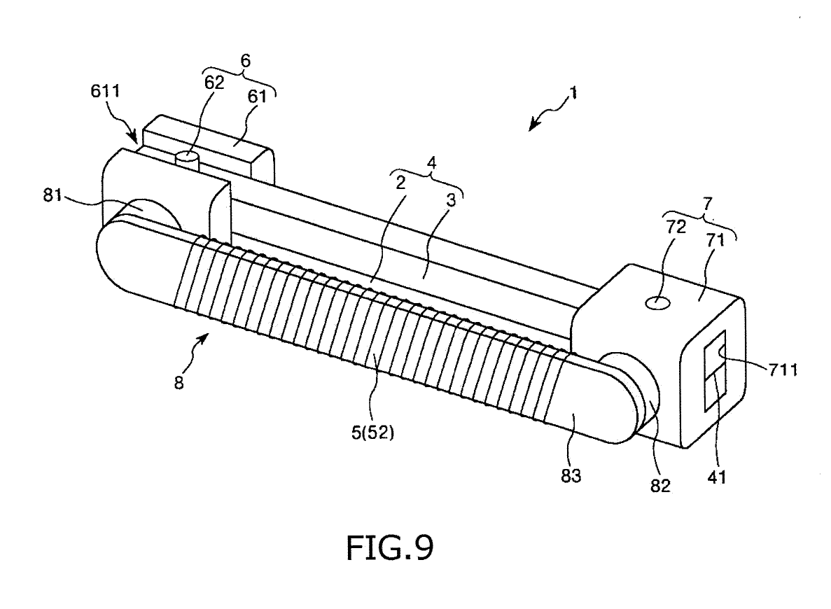

FIG. 9 is a longitudinal cross-sectional view showing the power generating element according to the fifth embodiment of the present invention. Hereinafter, an upper side in FIG. 9 is referred to as “upper” or “upper side” and a lower side in FIG. 9 is referred to as “lower” or “lower side”. Further, a right side in FIG. 9 is referred to as “distal side” and a left side in FIG. 9 is referred to as “proximal side”.

Hereinafter, the power generating element according to the fifth embodiment will be described by placing emphasis on the points differing from the power generating elements according to the first to the fourth embodiments, with the same matters being omitted from description.

A power generating element 1 according to the fifth embodiment has the same configuration as the power generating element 1 according to the first embodiment except that the arrangement (position) of the coil 5 is modified. Namely, as shown in FIG. 9, in the power generating element 1 according to the fifth embodiment, the coil 5 is formed by winding the wire 52 around not the composite rod 4 but the yoke 83. In other words, the coil 5 is provided so that the lines of magnetic force pass inside the coil 5 (the inner cavity of the coil 5) in the axial direction of the coil 5 (in this embodiment, the axial direction of the coil 5 is equivalent to an axial direction of the yoke 83) after passing through the magnetostrictive rod 2.

The power generating element 1 according to the fifth embodiment can also provide the same functions/effects as the power generating elements 1 according to the first to the fourth embodiments.

The power generating element as described above can be applied to a power supply for a transmitter, a power supply for a sensor network, a wireless switch for house lighting, a system for monitoring status of each component of vehicle (for example, a tire pressure sensor and a sensor for seat belt wearing detection), a home security system (in particular, a system for wirelessly informing detection of operation to a window or a door) or the like.

Although the power generating element of the present invention has been described with reference to the accompanying drawings, the present invention is not limited thereto. In the power generating element, the configuration of each component may be possibly replaced by other arbitrary configurations having equivalent functions. It may be also possible to add other optional components to the present invention. For example, it may be also possible to combine the configurations according to the first embodiment to the fifth embodiments of the present invention in an appropriate manner.

Further, one of the two permanent magnets may be omitted from the power generating element and one or both of the two permanent magnets may be replaced by an electromagnet. Furthermore, the power generating element of the present invention can have another configuration in which the permanent magnets are omitted from the power generating element and the power generation of the power generating element may be achieved by utilizing an external magnetic field.

Further, although both the magnetostrictive rod and the reinforcing rod have the rectangular cross-sectional shape in each of the embodiments, the present invention is not limited thereto. Examples of the cross-sectional shapes of the magnetostrictive rod and the reinforcing rod include a circular shape, an ellipse shape and a polygonal shape such as a triangular shape, a square shape and a hexagonal. Among them, it is preferred that both of the magnetostrictive rod and the reinforcing rod have a shape having a flat joint surface (in particular, the rectangular shape) from a point of view of ensuring a jointing strength between the magnetostrictive rod and the reinforcing rod.

### INDUSTRIAL APPLICABILITY

According to the present invention, it is possible to cause uniform stress in the magnetostrictive rod when the magnetostrictive rod is expanded or contracted by using the composite rod obtained by jointing the magnetostrictive rod and the reinforcing rod which has the function of causing appropriate stress in the magnetostrictive rod. As a result, it is possible to improve the power generating efficiency of the power generating element. For the reasons stated above, the present invention is industrially applicable.

### DESCRIPTION OF REFERENCE NUMBER

1 . . . power generating element; 2 . . . magnetostrictive rod; 21 . . . main body; 211 . . . through-hole; 22 . . . thin wall portion; 221 . . . through-hole; 3 . . . reinforcing rod; 4 . . . composite rod; 41 . . . joint portion; 5 . . . coil; 51 . . . bobbin; 52 . . . wire; 511 . . . gap; 6 . . . first coupling portion; 61 . . . main body; 611, 612 . . . groove; 613 . . . through-hole; 62 . . . pin; 7 . . . second coupling portion; 71 . . . main body; 711 . . . inserted portion; 712, 713 . . . through-hole; 72 . . . pin; 8 . . . magnetic field applying mechanism; 81, 82 . . . permanent magnet; 83 . . . yoke

1. A power generating element comprising:
a composite rod having one end portion and the other end portion, the composite rod including,
a magnetostrictive rod through which lines of magnetic force pass in an axial direction thereof, the magnetostrictive rod formed of a magnetostrictive material, and
a reinforcing rod having a function of causing appropriate stress in the magnetostrictive rod, the reinforcing rod arranged in parallel with the magnetostrictive rod and formed of a non-magnetic material,
wherein the composite rod is obtained by jointing the magnetostrictive rod and the reinforcing rod through a joint portion; and
a coil provided so that the lines of magnetic force pass inside the coil in an axial direction of the coil and in which a voltage is generated on the basis of variation of density of the lines of magnetic force,
wherein the power generating element is configured so that the density of the lines of magnetic force varies when the other end portion of the composite rod is relatively displaced toward a direction substantially perpendicular to an axial direction of the composite rod with respect to the one end portion of the composite rod to expand or contract the magnetostrictive rod.

2. The power generating element as claimed in claim 1, wherein when an average value of a cross-sectional area of the magnetostrictive rod is defined as “A” [mm2] and an average value of a cross-sectional area of the reinforcing rod is defined as “B” [mm2], “A” and “B” satisfy a relationship of B/A≧0.8.

3. The power generating element as claimed in claim 1, wherein a cross-sectional area of a part of the composite rod corresponding to the joint portion decreases from the one end portion toward the other end portion of the composite rod.

4. The power generating element as claimed in claim 1, wherein a cross-sectional area of a part of the reinforcing rod corresponding to the joint portion decreases from the one end portion toward the other end portion of the composite rod, and
wherein a cross-sectional area of the magnetostrictive rod is substantially constant from the one end portion toward the other end portion of the composite rod.

5. The power generating element as claimed in claim 1, wherein the coil is arranged around a part of the composite rod corresponding to the joint portion so as to surround the composite rod.

6. The power generating element as claimed in claim 1, wherein the coil includes a bobbin arranged around a part of the composite rod corresponding to the joint portion so as to surround the composite rod and a wire wound around the bobbin.

7. The power generating element as claimed in claim 6, wherein a gap is formed between the composite rod and the bobbin on at least a side of the other end portion of the composite rod.

8. The power generating element as claimed in claim 7, wherein a displacement of the other end portion of the composite rod is caused by applying vibration to the composite rod, and
wherein the gap is formed so as to have a size so that the bobbin and the composite rod do not mutually interfere while the composite rod is vibrated.

9. The power generating element as claimed in claim 1, wherein a Young's modulus of the magnetostrictive material is substantially equal to a Young's modulus of the non-magnetic material.

10. The power generating element as claimed in claim 1, wherein a Young's modulus of each of the magnetostrictive material and the non-magnetic material is in the range of 40 to 100 GPa.

11. The power generating element as claimed in claim 1, wherein the magnetostrictive material contains an iron-gallium based alloy as a main component thereof.

12. The power generating element as claimed in claim 1, wherein the non-magnetic material contains at least one selected from the group consisting of aluminum, magnesium, zinc, copper and an alloy containing at least one of these materials as a main component thereof.
